(19) United States
(12) Patent Application Publication
(10) Pub. No.: US 2018/0268040 A1
(43) Pub. Date: Sep. 20, 2018

(54) Online Data Compression and Decompression

(71) Applicant: CA, Inc., New York, NY (US)

(72) Inventors: Kevin P. Shuma, Celina, TX (US); Joseph Lynn, Plano, TX (US); Robert Florian, Dallas, TX (US)

(21) Appl. No.: 15/463,435

(22) Filed: Mar. 20, 2017

(51) Int. Cl. G06F 17/30; H03M 7/30

(52) U.S. Cl. CPC G06F 17/30569; H03M 7/30; G06F 17/30362

(57) ABSTRACT

A computer device provides an “on-demand” technique for compressing the rows of a dataset separately from all other rows of data in the dataset. Users are presented with a list of predetermined compression techniques, and select one of the techniques. The computer then executes the selected compression technique to compress the dataset on a row-by-row basis. As each row of data is being compressed, the dataset remains on-line such that users still have access to the other rows of data in the dataset. Decompression of the rows of data in the dataset are also implemented on a row-by-row basis.

### BACKGROUND

The present disclosure relates generally to computer devices configured to compress and decompress rows of a dataset.

Data compression techniques generally reduce the size of a given dataset by encoding the data in the dataset using fewer bits than the original representation. There are many known techniques or algorithms for compressing datasets, but they are typically classified as being either “lossy” (i.e., techniques that reduce the size of a dataset by eliminating unnecessary information), or “lossless” (i.e., techniques that reduce the size of a dataset by identifying and eliminating statistical redundancies in the dataset).

Historically, the use of data compression has been driven, at least in part, by the cost of storing uncompressed data on a disk versus the cost of the processing power required for compression. By way of example only, the cost of processing power required for compressing datasets on a mainframe computer was more expensive than the cost of storing uncompressed data on a disk. Thus, rather than compress data prior to storage, many devices simply stored the data uncompressed. Over time, though, that calculus has changed. With the introduction of certain processors, such as the IBM® z Systems Integrated Information Processor (zIIP), for example, the cost of the processing power needed for compression is now much less than the cost of storing the uncompressed data. Thus, more mainframe datasets are now being compressed before storage.

### BRIEF SUMMARY

Embodiments of the present disclosure provide for the compression of the rows in a dataset on a row-by-row basis without interrupting user access to all of the other rows of the dataset.

In one embodiment, the present disclosure provides a method implemented, for example, on a mainframe computer. Particularly, in this embodiment, a data compression algorithm (i.e., a data compression technique) is determined for use in compressing the data of a dataset, which comprises a plurality of dataset rows. The rows of the dataset are compressed according to the data compression technique on a row-by-row basis. However, while the dataset is being compressed on a row-by-row basis, the data within the dataset is still accessible to a user.

In one embodiment, a computer (e.g., a mainframe computer) comprises a communication interface circuit and a processing circuit. The communication interface circuit is configured to communicate data with a network. The processing circuit is operatively connected to the communication interface circuit, and is configured to determine a data compression technique for use in compressing a dataset. The dataset comprises a plurality of dataset rows. Additionally, the processing circuit is configured to compress the dataset on a row-by-row basis according to the data compression technique, and make data within the dataset accessible to a user while the dataset is being compressed on a row-by-row basis.

In one embodiment, a non-transitory computer-readable storage medium comprises instructions stored thereon that, when executed by a processing circuit of a computer, causes the computer to determine a data compression technique for use in compressing a dataset, which comprises a plurality of dataset rows, compress the dataset on a row-by-row basis according to the data compression technique, and make data within the dataset accessible to a user while the dataset is being compressed on a row-by-row basis.

Of course, those skilled in the art will appreciate that the present embodiments are not limited to the above contexts or examples, and will recognize additional features and advantages upon reading the following detailed description and upon viewing the accompanying drawings.

### BRIEF DESCRIPTION OF THE DRAWINGS

Aspects of the present disclosure are illustrated by way of example and are not limited by the accompanying figures with like references indicating like elements.

FIG. 1 is a functional block diagram of a computer system configured according to one embodiment of the present disclosure.

FIG. 2 is a flow diagram illustrating a method of compressing the rows of a dataset according to one embodiment of the present disclosure.

FIG. 3 is a flow diagram illustrating a method for compressing the rows of a dataset without interrupting user access to the data within the dataset according to one embodiment of the present disclosure.

FIG. 4 is a flow diagram illustrating a method for changing the compression technique for use in compressing the dataset rows according to one embodiment of the present disclosure.

FIG. 5 is a flow diagram illustrating a method for resuming compression after an abnormal termination of compression operations according to one embodiment of the present disclosure.

FIG. 6 is a functional block diagram illustrating some functional components of a mainframe computer configured to perform embodiments of the present disclosure.

### DETAILED DESCRIPTION

As will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely as hardware, entirely as software (including firmware, resident software, micro-code, etc.) or combining software and hardware implementation that may all generally be referred to herein as a “circuit,” “module,” “component,” or “system.” Furthermore, aspects of the present disclosure may take the form of a computer program product embodied in one or more computer readable media having computer readable program code embodied thereon.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as assembler language, the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatuses (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

Accordingly, embodiments of the present disclosure provide an “on-demand” technique for compressing rows of data in a dataset (e.g., a data table or block of data) without interrupting user access to the data in the dataset during compression. With the present embodiments, users select a desired compression technique from among a predetermined number of different compression techniques to apply to the rows of data. The selected compression technique is then executed to compress each row of data in the dataset on a row-by-row basis. That is, each row of the dataset is compressed independently of all the other rows in the dataset. As each row of data is compressed, however, users still have access to all the other rows of data in the dataset thereby enabling the users to read and modify existing data rows, as well as add new data rows and delete other data rows. Once compression of a data row completes, the data row becomes immediately available for user processing.

Compression according to the present embodiments executes as a background process while the dataset remains on-line and active for users. Generally, the compression of a dataset will be interrupted whenever a system failure (or some other find of error that negatively affects compression) occurs. With conventional systems, compression of the dataset must begin anew once the system has been restored. A computer configured according to the present embodiments, however, tracks the status of compression while the data is being compressed. Because the computer maintains the compression status during compression, such system failures do not doom compression in the present disclosure. Rather, the computer is able to autonomously return to compressing the rows of data beginning with the row that was being compressed when the failure occurred.

Moreover, current technology dictates that the same compression technique be utilized to compress the contents of an entire dataset. Thus, under conventional wisdom, all rows of data in a given dataset are compressed using the same compression technique. With the present embodiments, however, different rows in a single, given dataset may be compressed according to different compression techniques. That is, some rows of data in the dataset may be compressed according to a first compression technique, while other rows of data in the dataset may be compressed according to a second, different technique. Further, this selection of a particular compression technique for a particular row of data in the dataset is user-controlled. Thus, in some embodiments, all rows in a given dataset will eventually be compressed and stored according to the same compression technique. In other embodiments, however, the dataset may be stored after compression is complete with different rows having been compressed according to different compression techniques.

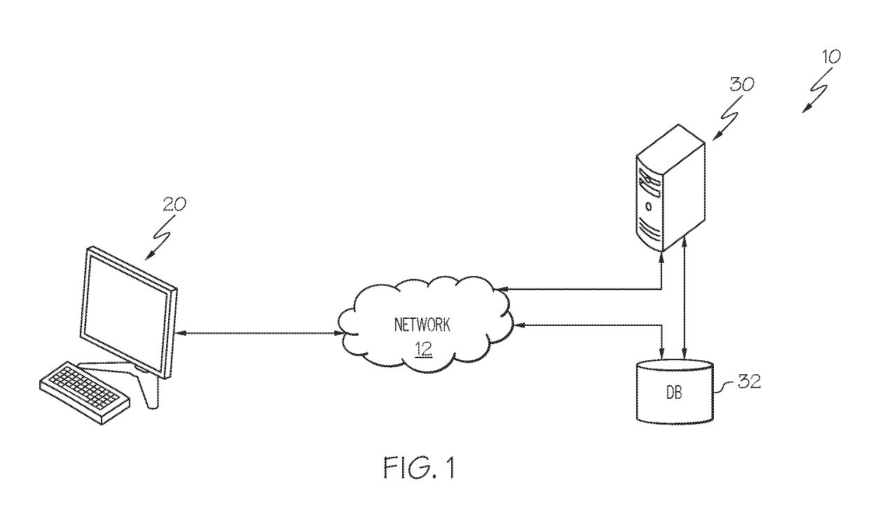

Turning now to the drawings, FIG. 1 is a functional block diagram illustrating a computer system 10 configured according to one embodiment of the present disclosure. It should be noted that the description and the figures disclose the present embodiments in the context of a mainframe computing environment; however, this is for ease of explanation and illustrative purposes only. Those of ordinary skill in the art should readily appreciate that the present embodiments are not limited merely to a mainframe computing context, but rather, are applicable to any type of computing system known in the art.

System 10 comprises one or more IP networks 12, such as packet data networks, for example, communicatively interconnecting a client device 20 (e.g., a user terminal, for example), a mainframe computer 30, and a persistent storage device (DB) 32. Although not expressly shown, other networks, network devices, and devices that connect to network 12, may be present in system 10 as needed or desired.

The mainframe 30 may comprise, for example, an IBMz13 or IBM zEnterprise EC12 mainframe computer. In operation, mainframe 30 executes one or more application programs that provide access to the data stored in DB 32. Such data may be stored in any manner needed or desired, but in one embodiment, is stored as rows of data in one or more data tables or data blocks, referred to herein as “datasets.” Client device 20 executes an end-user application, such as a browser application, that communicates with the one or more application programs executing on mainframe 30. Using the browser, the user is able to invoke various user interfaces (UIs) provided by the application programs executing on mainframe 30 to view, add, delete, modify, and otherwise manipulate the rows of data in the datasets on DB 32.

According to embodiments of the present disclosure, mainframe 30 is also configured to compress and decompress the rows of data in the dataset on a row-by-row basis. Compression is executed as a background process in accordance with a particular compression technique selected by a user, and further is performed while the entire dataset remains active and on-line. Thus, users may access any row in the dataset that is not currently being compressed even though other rows in the dataset are being compressed.

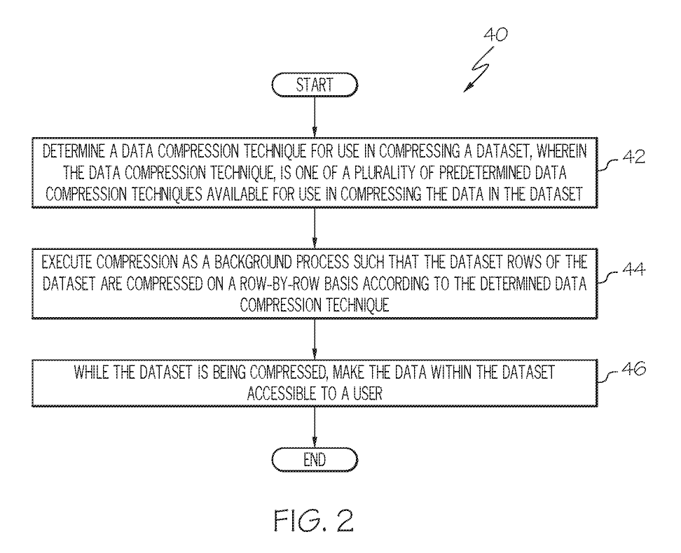

FIG. 2 is a flow diagram illustrating a method 40 for compressing the rows of a given dataset according to one embodiment of the present disclosure. As previously stated, the dataset is on-line and active such that users are able to access, read, add, delete, and modify the data in the dataset. In this embodiment, the method 40 is performed by the mainframe 30; however, those of ordinary skill in the art should realize that this if for illustrative purposes only. Method 40 may be executed on client device 20 or on any computing device that is operatively connected to the data stored in DB 32 and network 12.

As seen in FIG. 2, method 40 begins with mainframe 30 determining a data compression technique for use in compressing the data rows of a given dataset (box 42). This may be accomplished in any number of ways, but in one embodiment, the user selects a desired compression technique from a list of available compression techniques displayed in a dialog window. The number and types of compression techniques on the list are predetermined, but may be any compression scheme needed or desired. The compression techniques on the list may include “lossy” algorithms (i.e., techniques that reduce the size of a dataset by eliminating unnecessary information), “lossless” algorithms (i.e., techniques that reduce the size of a dataset by identifying and eliminating statistical redundancies in the dataset), or a combination of both lossy and lossless techniques. Some compression techniques that are suitable for use with the embodiments of the present disclosure include, but are not limited to, simple compression and Huffman encoding.

With simple compression, known strings of insignificant characters within a data row are replaced with a token (i.e., a bit pattern that cannot occur in normal data). Further, different tokens may be used for different strings, or even the same strings located at different positions within the data row. For example, a string of three consecutive blanks between words in a data row might be replaced with a first specific token, while trailing blanks at the end of the data row may be replaced using a different token.

Huffman encoding compression is where a particular type of optimal prefix code (or token) is commonly used for lossless data compression. There are varying forms of Huffman encoding where existing know data strings are replaced with a standard token; however, the implementation of a Huffman encoding algorithm typically focuses on replacing the “most likely occurring strings,” with some Huffman encoding algorithms being “stronger” than others.

In particular, the level of effort (i.e., computer cycles) required by the processor to perform compression using a Huffman encoding algorithm increases with the number of “less likely” strings (i.e., strings that have a lower likelihood of occurrence) that are searched for and replaced. Replacing only the most likely occurring strings is considered “weak” compression because only minimal effort is used to reduce the size of the data row. Replacing a much larger set of known strings, however, is considered “strong” compression. With “strong” compression, the amount of compression is significantly higher, but because more strings are searched for and replaced, the processing cost is also higher.

“Custom” compression is where each dataset is scanned, and a specific set of recurring data strings is stored in a table, for example, in memory. A specific token is then assigned to each string and stored in the table along with its corresponding string. The custom compression assignments are then saved in computer memory accessible to the processor performing the compression so that the processor can utilize the assignments whenever a data row is being compressed or decompressed.

As stated above, these particular encoding algorithms are merely illustrative. Thus, the present embodiments are not limited to these particular encoding algorithms, but rather, can employ other encoding techniques not expressly discussed here. Additionally, the present embodiments are not limited to known techniques that are already in existence. Some embodiments of the present disclosure, for example, may perform compression/decompression using a “user-defined” encoding technique. Such user-defined techniques may comprise any computer logic that configures a processor to compress and decompress a data row. Such user-defined compression algorithms are typically very specific in nature (i.e., specific to the particular data and/or type of data being compressed or decompressed) and are generally utilized where the data patterns are well defined.

Regardless of the particular compression technique, once the user has selected a desired compression technique from the list, mainframe 30 executes the selected compression technique as a background process such that the dataset is compressed according to the selected technique on a row-by-row basis (box 44). Further, the dataset remains active and on-line so that users can still access and manipulate the data in the dataset while the rows of the dataset are being compressed (box 46).

Such row-by-row compression of a dataset differs from those utilized in conventional dataset compression processes. For example, conventional processes generally require an administrator or similarly authorized user to first “unload” the dataset prior to beginning compression. Once unloaded, the administrator can execute the functions to compress the dataset. However, unloading a dataset necessarily takes the entire dataset off-line so that the data in the dataset is wholly unavailable to users. Further, the dataset remains off-line during compression, and thus, no users can access the dataset data during compression. The data in the dataset remains inaccessible until the administrator “loads” the dataset once again. Such loading does not occur, however, until after data compression has been completed. Therefore, conventional processes require outages to implement, which can by very costly.

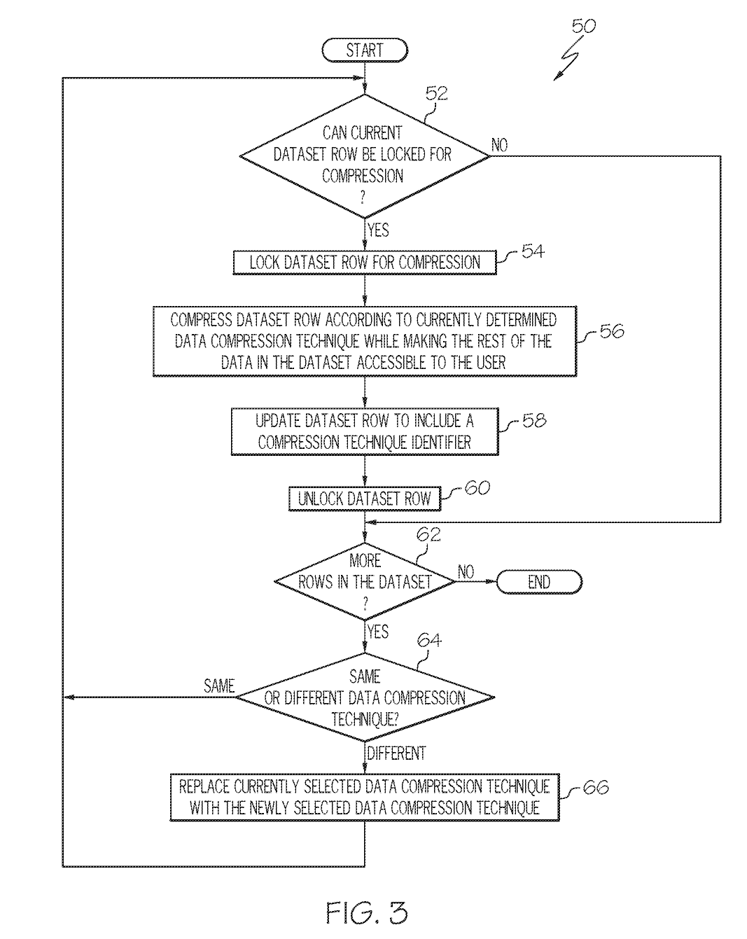

As stated above, the present embodiments compress the dataset utilizing a user-selected compression technique on a row-by-row basis thereby allowing end-users to continue to access and manipulate the data in the dataset while the dataset is being compressed. FIG. 3 is a flow diagram illustrating a method 50 for compressing a given dataset according to the present embodiments.

Method 50 may be implemented on any computer, but in this embodiment, is implemented by mainframe 30. Further, it should be noted that method 50 of FIG. 3 assumes that the user has already selected a desired compression technique from the list of compression techniques that are available to the user.

Compression of a given data row requires that row to be exclusively locked. While locked, the row is not accessible to the end users even though the other data rows are accessible to the users. This prevents the row from being changed by a user while it is being compressed. However, such locking is “atomic” and does not last very long (e.g., on the order of a few milliseconds). Therefore, any effect that locking a given data row has on a user's ability to access that row is minimal and generally not noticeable to the user.

Method 50 begins with mainframe 30 determining whether the current data row in the dataset can be locked for compression (box 52). In this embodiment, if mainframe 30 determines that the data row cannot be locked (e.g., the row of data is already being accessed by another user, for example), mainframe 30 will skip the compression of that data row and proceed to the next data row in the dataset (box 62). In these cases, the mainframe 30 may come back through the dataset and compress each row it was not able to compress earlier according to the selected compression technique. Otherwise, if the data row is able to be locked, such as when no user is currently accessing the data row, for example, mainframe 30 locks the data row for compression (box 54). While the data row is locked, mainframe 30 compresses the locked data row according to the selected compression technique while the rest of the dataset rows remain accessible to the user (box 56).

In some embodiments, prior to compression, mainframe 50 may update the data row being compressed to identify the particular compression technique that was used to compress that data row (box 58). For example, mainframe 30 may insert an ID or other indicator value that uniquely identifies the particular compression technique that was utilized to compress that data row. Such information is helpful for a number of reasons. For example, as described in more detail below, embodiments of the present disclosure allow for different compression techniques to be used to compress different data rows. Thus, a first data row in the dataset may be compressed using a first technique, while a second, different data row may be compressed using a second, different technique.

Such situations can occur for any number of reasons. For example, as the present disclosure provides “on-demand” compression, a user can select a new compression technique while the data rows of the dataset are currently undergoing compression according to a previously selected technique. In such cases, the mainframe 30 may cease compressing the dataset using the previous technique and begin compressing the dataset using the newly-selected technique. All of the data rows in the dataset may or may not eventually be compressed using the same compression technique; however, for at least some period of time, the dataset will comprise data rows that have been compressed using different techniques. Placing a compression ID in the data row will facilitate decompression operations for the dataset on a row-by-row basis.

In another embodiment, different data row types may be stored in the same dataset. In such cases, row-by-row compression could allow the user to assign a compression technique according to the data row type. The particular compression technique assigned to a given data row could be indicated, for example, by marking the data rows with a corresponding compression technique ID. Alternatively, or additionally, the particular compression technique assigned to a given row (or dataset) can be based on the data content itself. Such may be, for example, a “user-defined” compression technique as previously described.

Regardless of the ID, however, mainframe 30 unlocks the data row once compression of that data row is complete (box 60) before moving on to the next data row in the dataset (box 62). So unlocked, users are able to access the data in that row to add, modify, and delete the data. In particular, the data row is decompressed according to the ID stored with the data row, in some cases altered, and then compressed using whatever current compression technique the user selected. If there are no more data rows to be compressed (e.g., all the data rows in the dataset have been compressed using the same or different technique), method 50 ends. Otherwise, mainframe 30 determines whether it is to utilize the same user-selected compression technique for the next data row, or whether the user has selected a new compression technique (box 64). If the user has selected a new compression technique, mainframe 30 replaces the currently selected compression technique with the newly-selected technique (box 66) and repeats method 50 using the newly-selected compression technique. Otherwise, mainframe 30 simply repeats the compression on the next data row in the dataset.

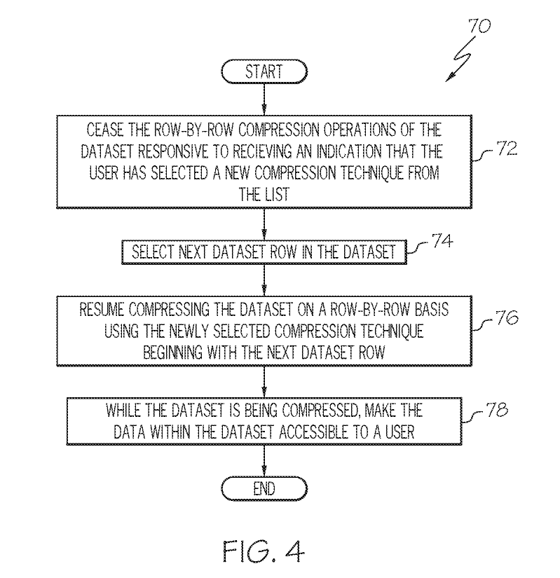

FIG. 4 is a flow diagram illustrating a method 70 in which mainframe 30 switches the technique it uses for compressing the rows of data in the dataset from a first, currently selected compression algorithm to a second, newly-selected compression technique from the list. Particularly, mainframe 30 ceases the row-by-row compression operations of the dataset using the current compression technique responsive to receiving an indication that the user has selected a new compression technique from the list of compression techniques (box 72). Once compression operations have ceased, mainframe 30 selects the next data row in the dataset (box 74) and resumes the row-by-row compression of the dataset beginning with that data row (box 76).

As stated above, even though the row-by-row compression of the entire dataset may not have been finished at the time the user selected the new compression technique, embodiments of the present disclosure configure mainframe 30 to allow different compression techniques to be utilized to compress different data rows in the same dataset. Further, mainframe 30 executes compression as a background process. Therefore, the entirety of the dataset may eventually be compressed on a row-by-row basis using the newly selected compression technique. This would mean that each data row that was compressed in accordance with a previously selected compression technique would first be locked, uncompressed in accordance with the compression technique identified in the data row, re-compressed using the newly-selected compression technique, and then unlocked so that user could once again read, add data to, delete data from, and modify the data row. Alternatively, the dataset may store the data rows compressed according to multiple different compression techniques, as previously described.

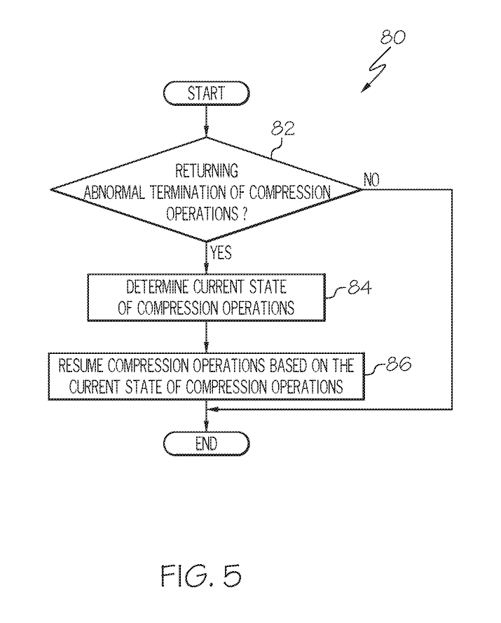

FIG. 5 illustrates a method 80 performed by mainframe 30 responsive to an abnormal termination of its functions while it is still compressing the dataset on a row-by-row basis. As seen in FIG. 5, mainframe 30 detects when it is returning from being terminated abnormally, such as during a reboot procedure after a system crash, for example, (box 82). Upon detecting its return, mainframe 30 determines the current state of the compression operations (box 84).

For example, using any method known in the art, mainframe 30 may identify the last (i.e., most recent) data row that was being processed according to the selected compression technique. In one embodiment, for example, the status of the compression is stored in a file (e.g., a control file or log file) that is updated as compression progresses. An “activity flag” or other indicator could be utilized to particularly indicate the particular data row that was being compressed at the time the process terminated abnormally. The file is stored persistently such that it survives abnormal termination of the compression process and is accessible to mainframe 30. Upon returning, mainframe 30 could access that file and determine where compression left off based on the flag. So identified, mainframe 30 can then resume compression of the dataset on a row-by-row basis using the currently selected compression technique, while leaving the remaining data rows accessible to the user, beginning with this identified data row (box 86).

It should be noted that with the present embodiments, even the loss of a system control file, log file, or other file that maintains a record of the progress of the compression activity with respect to a given dataset is not fatal. Rather, the dataset remains usable and compression operations can easily be restarted. Particularly, each data row in the dataset carries the identity of the particular compression technique used to compress that row. In cases where compression could not be automatically resumed due to the loss of the system control file (or other file having the compression progress), the user could just resubmit a compression technique request with the same selected compression technique, and the process would start over with the rows already identified as being compressed by the technique selected by the user being skipped. Should the user enter a different technique, the row-by-row compression would simply begin again using the newly-selected compression technique.

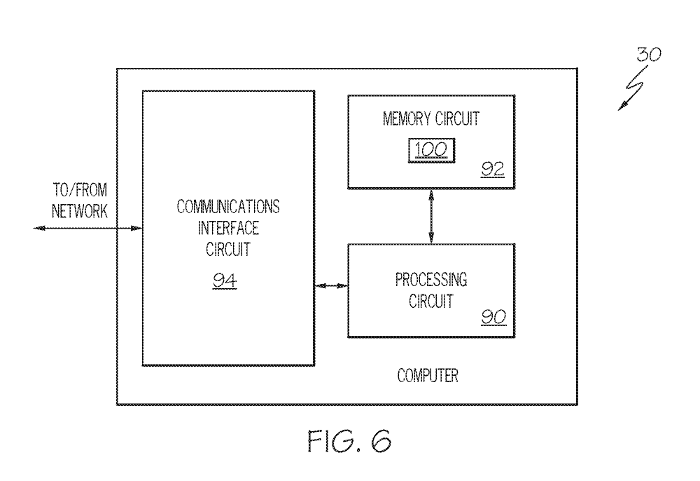

FIG. 6 is a functional block diagram illustrating mainframe 30 configured according to one embodiment of the present disclosure. As seen in FIG. 6, mainframe 30 comprises a processing circuit 90, a memory circuit 92 configured to store a control application 100, and a communications interface circuit 94.

Processing circuit 90 may be implemented by one or more microprocessors, hardware, firmware, or a combination thereof, and generally controls the operation and functions of mainframe 30 according to the appropriate standards. Such operations and functions include, but are not limited to, communicating with client device 20 and DB 32 via network 12, as previously described. In this regard, processing circuit 90 may be configured to the implement logic and instructions of the control application 100 stored in memory circuitry 92 to perform the embodiments of the present disclosure as previously described.

Memory circuit 92, which may be removable, or fixed, can comprise any non-transitory, solid state memory or computer readable media known in the art. Suitable examples of such media include, but are not limited to, random access memory (RAM), non-volatile memory, such as EPROM, EEPROM, and/or flash memory, a combination of volatile and non-volatile memory, magnetic storage devices, and optical storage devices. Memory circuit 92 may be implemented as one or more discrete devices, stacked devices, and/or integrated with processing circuit 90. However, regardless of its physical structure, memory circuit 92 is configured to store a control application 100. Control application 100, as stated above, includes the logic and instructions that, when executed by processing circuit 90, causes mainframe 30 to perform the embodiments of the present disclosure as previously described.

Communications interface circuit 94 comprises the communications circuitry that enables mainframe 30 to send data packets to, and receive data packets from, the client device 20 and DB 32 via IP network 12. By way of example only, communications interface circuit 94 may comprise one or more interface cards that operate according to any of standards that define the well-known ETHERNET protocol. However, other protocols and standards are also possible with the present disclosure.

The present embodiments may, of course, be carried out in other ways than those specifically set forth herein without departing from essential characteristics of the disclosure. For example, it should be noted that the flowchart and block diagrams in the Figures illustrate the architecture, functionality, and operation of possible implementations of systems, methods and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, to blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular aspects only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of any means or step plus function elements in the claims below are intended to include any disclosed structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The aspects of the disclosure herein were chosen and described in order to best explain the principles of the disclosure and the practical application, and to enable others of ordinary skill in the art to understand the disclosure with various modifications as are suited to the particular use contemplated.

Thus, the foregoing description and the accompanying drawings represent non-limiting examples of the methods and apparatus taught herein. As such, the present invention is not limited by the foregoing description and accompanying drawings. Instead, the present invention is limited only by the following claims and their legal equivalents.

What is claimed is:

1. A method implemented by a computer, the method comprising:
determining a data compression algorithm for use in compressing a dataset, wherein the dataset comprises a plurality of dataset rows;
compressing the dataset on a row-by-row basis according to the data compression algorithm; and
while the dataset is being compressed on a row-by-row basis, making data within the dataset accessible to a user.

2. The computer-implemented method of claim 1 wherein determining the data compression algorithm comprises selecting the data compression algorithm from a predetermined plurality of data compression algorithms based on user input.

3. The computer-implemented method of claim 1 wherein compressing the dataset on a row-by-row basis according to the data compression algorithm comprises compressing each dataset row according to the data compression algorithm as a background process.

4. The computer-implemented method of claim 1 wherein compressing the dataset on a row-by-row basis according to the data compression algorithm comprises:
for each dataset row being compressed:
locking the dataset row to prevent users from accessing the dataset row;
compressing the dataset row according to the data compression algorithm; and
unlocking the dataset row responsive to determining that the dataset row has been compressed.

5. The computer-implemented method of claim 1 further comprising switching the data compression algorithm being used to compress the dataset on the row-by-row basis while the dataset is being compressed on the row-by-row basis, such that the dataset comprises a first dataset row compressed according to a first data compression algorithm, and a second dataset row compressed according to a second data compression algorithm.

6. The computer-implemented method of claim 5 further comprising updating each dataset row being compressed with control information indicating which dataset compression algorithm was used to compress the dataset row.

7. The computer-implemented method of claim 5 wherein switching the data compression algorithm comprises:
ceasing compression of the dataset on the row-by-row basis according to the data compression algorithm;
resuming compressing the dataset on the row-by-row basis according to a different data compression algorithm; and
while the dataset is being compressed on the row-by-row basis according to the different data compression algorithm, making the data within the dataset accessible to the user.

8. The computer-implemented method of claim 1 wherein compressing the dataset on the row-by-row basis according to the data compression algorithm comprises:
compressing a first subset of the dataset rows on a row-by-row basis according to a first data compression algorithm; and
compressing a second subset of the dataset rows on a row-by-row basis according to a second data compression algorithm, wherein the first and second data compression algorithms are different.

9. The computer-implemented method of claim 1 further comprising:
determining a current state of compression for the dataset responsive to returning from an abnormal termination of compression operations, wherein the current state of compression for the dataset indicates:
the dataset row that was being compressed when the compression operations were abnormally terminated; and
the data compression algorithm that was being used to compress the dataset row at the time the compression operations were abnormally terminated; and
resuming the compression operations based on the current state of compression, wherein resuming compression operations comprises resuming compression of the dataset beginning with the indicated dataset row using the indicated data compression algorithm.

10. A computer comprising:
a communication interface circuit configured to communicate data with a network; and
a processing circuit operatively connected to the communication interface circuit and configured to:
determine a data compression algorithm for use in compressing a dataset, wherein the dataset comprises a plurality of dataset rows;
compress the dataset on a row-by-row basis according to the data compression algorithm; and
while the dataset is being compressed on a row-by-row basis, make data within the dataset accessible to a user.

11. The computer of claim 10 wherein to determine the data compression algorithm, the processing circuit is configured to select the data compression algorithm from a predetermined plurality of data compression algorithms based on user input.

12. The computer of claim 10 wherein to compress the dataset on a row-by-row basis according to the data compression algorithm, the processing circuit is further configured to compress each dataset row according to the data compression algorithm as a background process.

13. The computer of claim 10 wherein to compress the dataset on a row-by-row basis according to the data compression algorithm, the processing circuit is further configured to:
for each dataset row being compressed:
lock the dataset row to prevent users from accessing the dataset row;
compress the dataset row according to the data compression algorithm; and
unlock the dataset row responsive to determining that the dataset row has been compressed.

14. The computer of claim 10 wherein the processing circuit is further configured to switch the data compression algorithm being used to compress the dataset on the row-by-row basis while the dataset is being compressed on the row-by-row basis, such that the dataset comprises a first dataset row compressed according to a first data compression algorithm, and a second dataset row compressed according to a second data compression algorithm.

15. The computer of claim 14 wherein the processing circuit is further configured to update each dataset row being compressed with control information indicating which dataset compression algorithm was used to compress the dataset row.

16. The computer of claim 14 wherein to switch the data compression algorithm, the processing circuit is further configured to:
cease compression of the dataset on the row-by-row basis according to the data compression algorithm;
resume compressing the dataset on the row-by-row basis according to a different data compression algorithm; and
while the dataset is being compressed on the row-by-row basis according to the different data compression algorithm, make the data within the dataset accessible to the user.

17. The computer of claim 10 wherein to compress the dataset on the row-by-row basis according to the data compression algorithm, the processing circuit is further configured to:
compress a first subset of the dataset rows on a row-by-row basis according to a first data compression algorithm; and
compress a second subset of the dataset rows on a row-by-row basis according to a second data compression algorithm, wherein the first and second data compression algorithms are different.

18. The computer of claim 10 wherein the processing circuit is further configured to:
determine a current state of compression for the dataset responsive to returning from an abnormal termination of compression operations, wherein the current state of compression for the dataset indicates:
the dataset row that was being compressed when the compression operations were abnormally terminated; and
the data compression algorithm that was being used to compress the dataset row at the time the compression operations were abnormally terminated; and
resume the compression operations based on the current state of compression, wherein to resume compression operations the processing circuit is further configured to resume compression of the dataset beginning with the indicated dataset row using the indicated data compression algorithm.

19. A non-transitory computer-readable storage medium comprising instructions stored thereon that, when executed by a processing circuit of a computer, configures the computer to:
determine a data compression algorithm for use in compressing a dataset, wherein the dataset comprises a plurality of dataset rows;
compress the dataset on a row-by-row basis according to the data compression algorithm; and
while the dataset is being compressed on a row-by-row basis, make data within the dataset accessible to a user.

20. The non-transitory computer-readable storage medium of claim 19 wherein, when executed by the processing circuit, the instructions are further configured to control the computer to switch the data compression algorithm being used to compress the dataset on the row-by-row basis from a first data compression algorithm to a second data compression algorithm while the dataset is being compressed on the row-by-row basis
